(19) United States
(12) Patent Application Publication
(10) Pub. No.: US 2010/0096171 A1
(43) Pub. Date: Apr. 22, 2010

(54) Printed circuit board having round solder bump and method of manufacturing the same

(75) Inventors: Seok Kyu Lee, Gyunggi-do (KR); Jae Joon Lee, Gyunggi-do (KR); Ki Hwan Kim, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/320,366

(22) Filed: Jan. 23, 2009

(30) Foreign Application Priority Data
Oct. 20, 2008 (KR) 10-2008-0102682

(51) Int. Cl. H05K 1/09; B32B 38/10; H05K 1/11

(52) U.S. Cl. 174/257; 156/247; 174/261

(57) ABSTRACT

Disclosed herein is a printed circuit board having round solder bumps and a method of manufacturing the same. The solder bump is configured to have a round connecting surface in contact with a pad, and thus have an increased contact area with respect to the pad, thus improving connection reliability. The solder bumps have uniform heights.

### CROSS REFERENCE TO RELATED APPLICATION

This application claims the benefit of Korean Patent Application No. 10-2008-0102682, filed Oct. 20, 2008, entitled “A PRINTED CIRCUIT BOARD COMPRISING A ROUND SOLDER BUMP AND A METHOD OF MANUFACTURING THE SAME”, which is hereby incorporated by reference in its entirety into this application.

### BACKGROUND OF THE INVENTION

1. Field of the Invention

The present invention relates to a printed circuit board having round solder bumps and a method of manufacturing the same, and more particularly to a printed circuit board having round solder bumps and a method of manufacturing the same in which pad-connecting surfaces of bumps are rounded to increase a surface area contacting pads, thus increasing reliability of connection and ensuring uniform height of bumps.

2. Description of the Related Art

(The following lighted paragraphs are the same as those of the previous reviewed case, and will be replaced with the reviewed paragraphs. Hence, the paragraphs are not necessary to review) These days, with the development of electronic industry, demands for the miniaturization and the increase in the functionality of electronic components are rapidly increased, and printed circuit boards incorporating such electronic components therein also require high density wiring and thin substrates.

In particular, a typical build-up printed wiring board is manufactured in a manner such that a build-up layer is formed on a core substrate, and thus the resulting build-up printed wiring board product still contains the core substrate therein in use. Unfortunately, this causes increase in the total thickness of the printed wiring board. If a thickness of the printed wiring board is increased, the length of the wiring is elongated, and thus it involves increase in a time required for a signal processing.

To solve the above problems, a coreless substrate rather than a core substrate having a thick thickness has been proposed. FIGS. 1 to 5 show a process of manufacturing the conventional coreless substrate.

Hereinafter, a process of manufacturing the conventional coreless substrate is described with reference to FIGS. 1 to 5.

As shown in FIG. 1, a lower insulating layer 12 is first formed on a metal carrier 11 for supporting a coreless substrate.

As shown in FIG. 2, a build-up layer 13, which includes a circuit layer 13b composed of a plurality of build-up insulating layers 13a and a plurality of circuit layers 13b having vias 13c, is formed on the lower insulating layer 12, and an upper insulating layer 14 is formed on the build-up layer 13.

Subsequently, as shown in FIG. 3, upper openings 14a are formed in the upper insulating layer 14 such that upper pads of the uppermost circuit layer 13b contained in the build-up layer 13 are exposed through the upper openings 14a. At this point, the openings 14a may be formed using a drilling machining or a laser radiation.

As shown in FIG. 4, the metal carrier 11 is eliminated using etching.

Finally, as shown in FIG. 5, lower openings 12a are formed in the lower insulating layer 12 such that lower pads of the lowermost circuit layer 13b contained in the build-up layer 13 are exposed through the lower openings 12a, and then solder balls 15 are formed on the upper and lower pads for the connection with exterior connecting terminals.

Through the above-described process, the conventional coreless substrate 10 is manufactured.

However, the conventional coreless substrate 10 and the method of manufacturing the coreless substrate has following disadvantages.

First, since the conventional coreless substrate 10 is configured such that the upper and lower pads are exposed through the upper openings 14a and the lower openings 12a, respectively, as shown in FIG. 5, the coreless substrate may have stepped portions, which deteriorate matching accuracy between the solder balls 15 and the upper/lower pads and also deteriorate a bonding reliability.

Furthermore, since the conventional method of manufacturing a coreless substrate 10 involves the metal carrier 11 for supporting the coreless substrate 10 during the manufacturing process, manufacturing costs thereof are increased. In addition to this, since the method involves an etching process of eliminating the metal carrier 11, a manufacturing time is increased.

Also, since the build-up layer 13 is provided only at one side with respect to the metal carrier 11, productivity thereof is decreased. In addition, when the process of forming the build-up layer is conducted only at one side, products are seriously warped during the manufacturing process.

In addition, during drilling or laser machining of forming the upper openings 14a and the lower openings 12a in the upper insulating layer 14 and the lower insulating layer 12 so as to expose the upper and lower pads through the upper and lower openings, the coreless substrate 10 is warped, and stepped portions are inevitably generated between the pads and the openings 12a and 14a due to the thicknesses of the upper insulating layer 14 and the lower insulating layer 12.

Furthermore, when the metal mask and the thin coreless substrate 10 are bonded to each other in a screen printing process of forming solder balls or bumps for connecting the coreless substrate 10 with an electronic component, a clearance occurs therebetween, thus hindering an even application of solder onto the coreless substrate 10. Because of the above problems, uniformities of heights and diameters of solder balls or bumps are decreased in reflow and coining processes, thus decreasing a production yield.

In addition, in a back-end process such as a formation of solder balls 15, warp of products are drastically generated when conducting a process requiring application of a high temperature of 220° C. or more, as in an IR reflow. In the case of typical coreless FCB, as the number of times of conducting IR reflow is increased, warp of products becomes serious.

### SUMMARY OF THE INVENTION

Accordingly, the present invention has been made keeping in mind the above problems occurring in the prior art, and the present invention provides a printed circuit board having round solder bumps which have an increased area in contact with connecting pads thus improving connection reliability and have even heights, and a method of manufacturing the printed circuit board.

Also, the present invention provides a method of manufacturing a printed circuit board having round solder bumps, which reduces the number of reflow processes and coining processes and reduces generation of warp even without having a thick core and which is capable of accommodating solder bumps of fine pitches.

In one aspect, the present invention provides a printed circuit board including: a plurality of circuit layers disposed one on other; an insulating layer disposed between the plurality of circuit layers; a lower connecting pad formed in a lowermost circuit layer of the plurality of circuit layers; and a solder bump electrically connected to the lower connecting pad, in which a side of the solder bump, in contact with the lower connecting pad, has a round shape and the other side of the solder bump has a flat shape.

The lower connecting pad may have a concave round surface recessed in the insulating layer.

The printed circuit board may further include a connecting metal layer disposed between the lower connecting pad and the solder bump.

The printed circuit board may further include: an upper connecting pad formed in a uppermost circuit layer of the plurality of circuit layers; and a solder resist layer disposed on the uppermost circuit layer and having an opening through which the upper connecting pad is exposed.

The connecting metal layer may include a nickel plating layer.

In an another aspect, the present invention provides a method of manufacturing a printed circuit board, including: (A) forming a solder bump on a metal foil layered on a carrier, in which a pad-connecting surface of the solder bump, facing away from the carrier, has a round shape; (B) forming a lower pad-connecting metal layer on the metal foil including the solder bump; (C) forming a build-up layer on the lower pad-connecting metal layer, in which the build-up layer includes a circuit layer electrically connected to the solder bump and an insulating layer; (D) removing the carrier; and (E) removing the metal foil and an exposed portion of the lower pad-connecting metal layer.

In the method, (A) forming the solder bump may include: (i) disposing a printing mask on the metal foil layered on the carrier, in which the printing mask has an opening for formation of the solder bump, and printing the metal foil with solder paste; and (ii) conducting a reflow process and removing the printing mask thus forming the solder bump.

The circuit layer formed in a uppermost portion of the build-up layer may include an upper connecting pad, the method further comprising, after (C) forming the build-up layer, forming a solder resist layer on the circuit layer formed in the uppermost portion of the build-up layer, in which the solder resist layer has an opening through which the upper connecting pad is exposed.

The method may further include, after (A) forming the solder bump, forming a connecting metal layer on the metal foil including the solder bump, and (E) removing the metal foil and the exposed portion of the lower pad-connecting metal layer may include removing the connecting metal layer.

The carrier may include a copper clad laminate including an insulating layer and a thin copper layer layered on at least one side of the insulating layer and a release layer disposed on the copper clad laminate.

The printing mask may include a cover film having an opening for formation of the solder bump, in which the opening is formed in the cover film through an exposure/development process or a laser drilling process.

The printing mask may include a metal mask having an opening for formation of the solder bump.

The method may further include, after forming the solder resist layer, subjecting a surface of the solder resist layer to OSP (Organic Solderability Preservative) treatment or to formation of ENIG (Electroless Nickel Imersion Gold) layer.

The connecting metal layer may include a nickel plating layer.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 to 5 are cross-sectional views showing a conventional process of manufacturing a coreless substrate;

FIG. 6 is a cross-sectional view of a printed circuit board having round solder bumps according to an embodiment of the present invention; and

FIGS. 7 to 21 are cross-sectional view showing a process of manufacturing a printed circuit board having round solder bumps according to an embodiment of the present invention.

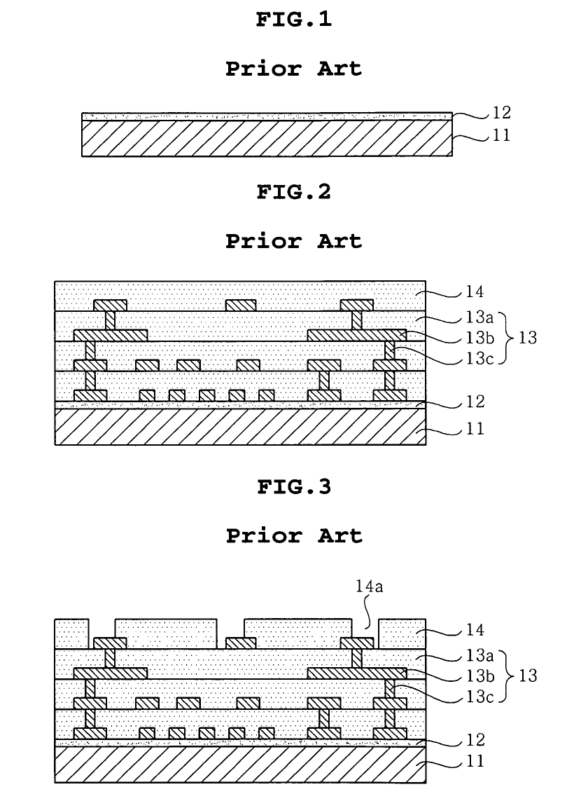

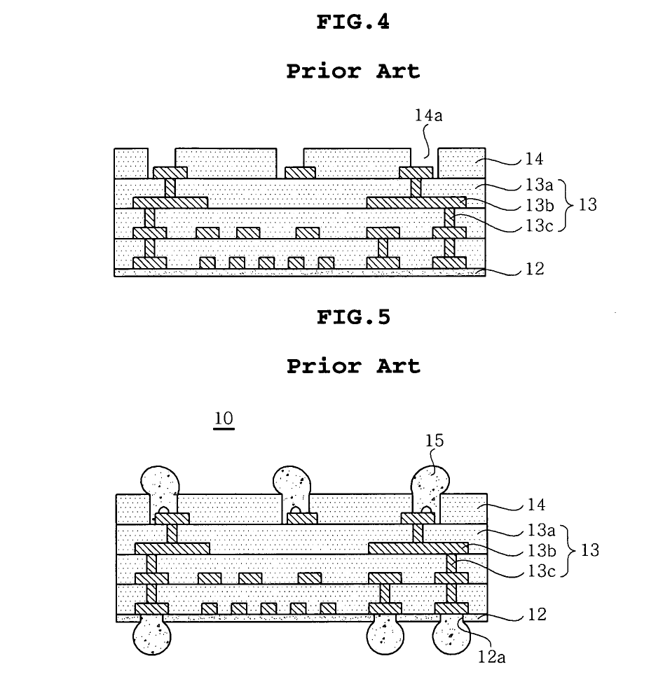

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

Hereinafter, a printed circuit board having round solder bumps according to the present invention will be described in greater detail with reference to the accompanying drawings. Throughout the accompanying drawings, the same reference numerals are used to designate the same or similar components, and redundant descriptions thereof are omitted. In the following description, the terms “upper”, “lower” and the like are used to differentiate a certain component from other components, but the configuration of such components should not be construed to be limited by the terms.

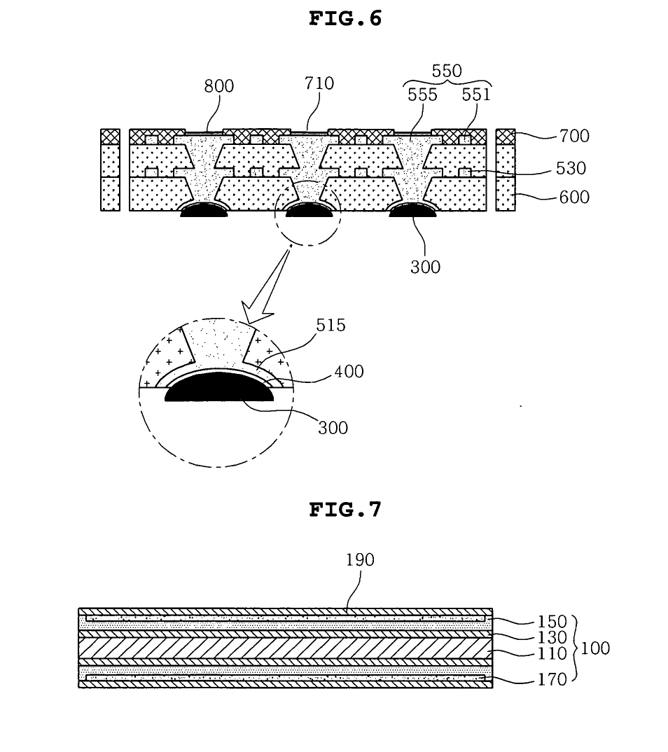

FIG. 6 is a schematic cross-sectional view of a printed circuit board having round solder bumps according to an embodiment of the present invention.

As shown in FIG. 6, the printed circuit board having round solder bumps according to this embodiment comprises a plurality of circuit layers which are disposed one on other, insulating layers 600 disposed between the circuit layers, a lower connecting pads 515 formed on the lowermost circuit layer, and round solder bumps 300 electrically connected to the lower connecting pads 515.

The printed circuit board (PCB) is intended to electrically connect components mounted thereon to each other through a circuit pattern formed on an insulating material such as a phenol resin insulating plate or an epoxy resin insulating plate, to supply the components with electric power, and to hold the components in a mechanical manner. The printed circuit board may be classified into a single-sided PCB in which a circuit layer is formed only on one side of an insulating material, a double-sided PCB in which circuit layers are formed on both sides of the an insulating material, and an MLB (Multilayered board) in which a plurality of circuit layers are wired.

Specifically, this embodiment is directed to a package substrate which enables electronic components to be mounted on a main board. Although FIG. 6 shows a multilayered board which is composed of two insulating layers 600 and three circuit layers, the present invention should not be understood to be limited to this configuration but may also be applied to a multilayered board having two or more circuit layers.

The lower connecting pads are formed on the lowermost layer of the circuit layers constituting the printed circuit board. The lower connecting pads 515 are configured to have a concave round shape defined in the insulating layer 600. Although the lower connecting pads 515 may be made of conductive material such as copper, gold, silver and nickel, the lower connecting pads 515 of this embodiment are made of copper.

Solder bumps 300 are electrically connected to the lower connecting pads 515, and are configured such that one side of each of the solder bumps which comes into contact with the pad has a round shape and the other side of the solder bump is flattened.

Connecting metal layers 400 may be disposed between the lower connecting pads 515 and the solder bumps 300. Although the connecting metal layers 400 are optional components and are not to be necessarily formed, they may be provided in order to prevent the lower connecting pads 515 and the solder bumps 300 from diffusing into each other. The connecting metal layers 400 are made of conductive material, and are made of material different from that of the lower connecting pads 515 in this embodiment. The printed circuit board according to this embodiment includes connecting metal layers 400 made of nickel.

The printed circuit board according to this embodiment further comprises upper connecting pads 555 formed in the upper most circuit layer 550, and a solder resist layer 700 formed on the uppermost circuit layer 550 and having openings 710 through which the upper connecting pads 555. At this point, an electroless nickel immersion gold layer 800 may be formed on the upper connecting pads 555.

Referring to FIG. 6, a circuit layer 530 is disposed between the uppermost circuit layer 550 and the lowermost circuit layer composed of the lower connecting pads 515, and a circuit pattern 551 is formed on the uppermost circuit layer 550.

The printed circuit board having round solder bumps according to this embodiment is configured such that all of the solder bumps 300 have the same height and a height of the bumps is substantially equal to a height of the insulating layer 600. Consequently, the coplanarity between the bumps and the insulating layer is achieved, thus ensuring reliable connection with electronic components mounted thereon.

Furthermore, since a pad-connecting surface of the round solder bump 300 has a round shape to increase a surface area in contact with the connecting pads, a bonding force between the solder bumps 300 and the connecting pads is increased. In addition, since the connecting pads are embedded in the insulating layer 600, it is possible to prevent the connecting pads from being separated from the board in a test such as a ball shear test, thus improving reliability of the solder bumps 300.

In addition, a non-wet phenomenon occurring between the bumps is reduced, resulting in improvement of production yield.

Furthermore, since a formation of bump under fill (BUF) becomes easy and a problem of void generation is cleared away, reliability after mount of electronic components such as chips is improved.

Hereinafter, a printed circuit board having round solder bumps according to an embodiment of the present invention is described. FIGS. 7 to 21 are cross-sectional views showing a process of manufacturing a printed circuit board having round solder bumps according to an embodiment of the present invention.

First, a process of forming solder bumps 300 on a metal foil 190 layered on a carrier 100 is conducted such that pad-connecting surfaces of the solder bumps 300 which face away from the carrier 100 have a round shape.

As shown in FIG. 7, a carrier 100, which serves as a support for preventing warp of the printed circuit board occurring during the manufacturing process, is prepared. For example, the carrier 100 comprises a double-sided copper clad laminate comprised of an insulating resin layer 110 and thin copper layers 130 formed on both sides of the insulating resin layer 110, insulating materials 150 formed on the double-sided copper clad laminate, and release layers 170 attached to the insulating materials 150.

In this regard, the double-sided copper clad laminate contains glass material to exhibit a predetermined rigidity, and may have a thickness of about 100-800 μm.

The release layer 170 may have a length and an area less than those of the thin copper layer 130, and may be formed on the insulating layers 150 except both lateral side areas. This configuration is intended to allow easy separation of the carrier 100 from the printed circuit board at the end of the manufacturing process. The release layers 170 may be constructed through a thin film coating process or a sputtering process. Metal foils are layered on the carrier 100 such that the metal foils are held by the portions of the insulating materials 150 at which the release layers 170 are not formed. The metal foils 190 may be made of conductive material such as copper, gold and silver, and this embodiment uses copper foils 190.

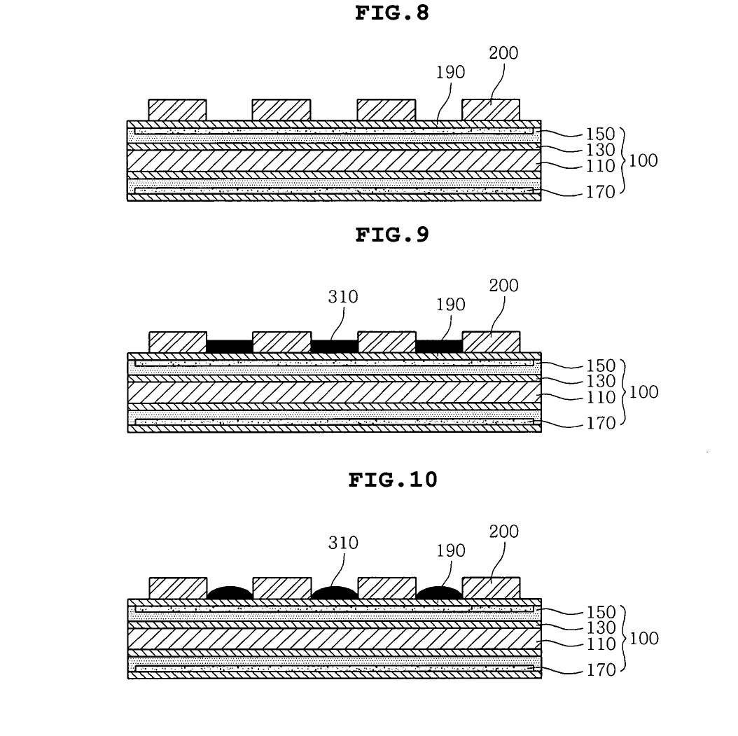

Subsequently, as shown in FIG. 8, a printing mask 200 having openings for the formation of solder bumps 300 is placed on the carrier 100. The printing mask 200, which is intended to conduct a print operation on positions at which the solder bumps 300 are to be formed, may be made of, for example, metal or cover film. In this embodiment, a cover film which is made of photosensitive resin is used as the printing mask 200. After the placement of the cover film on the carrier, the cover film is patterned to have openings for the formation of solder bumps 300 through an exposure/development process or a laser drilling process.

At this time, a height of the solder bumps 300 may be controlled by adjusting a thickness of the printing mask 200.

As shown in FIG. 9, the upper surface of the carrier 100 is printed with solder paste 310 through the openings of the printing mask 200 using a screen printing apparatus (not shown) such as a squeegee. The solder past 310 may be any one combination selected from among Sn/Pb, Sn/Ag/Cu, Sn/Ag, Sn/Cu, Sn/Bi, Sn/Zn/Bi and Sn/Ag/Bi.

Thereafter, as shown in FIG. 10, the solder bumps 300 are formed through a reflow process. With the aid of the reflow process, the solder bumps 300 have a desired configuration in which a pad-connecting surface of the solder bump 300, which faces away from the carrier 100, has a round shape while a surface of the solder bump 300, which is in contact with the metal foil 190, has a flat shape.

Subsequently, as shown in FIG. 11, the printing mask 200 is removed.

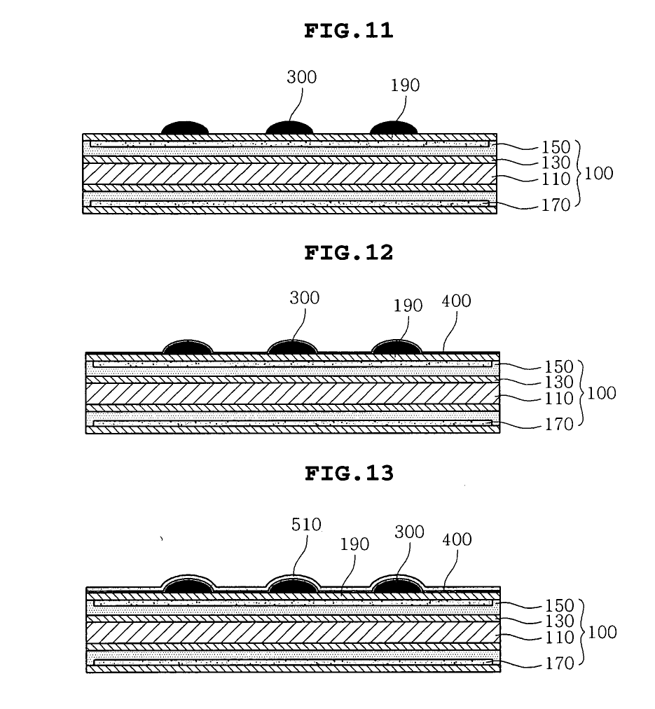

As shown in FIG. 12, a connecting metal layer 400 is formed on the carrier 100 including the solder bumps 300. The connecting metal layer 400 is provided between the lower connecting pads 515 (see FIG. 6) and the solder bumps 300 to prevent diffusion therebetween, and may be made of nickel. The connecting metal layer 400, which is an optional component, may be formed using electrolytic plating.

Thereafter, as shown in FIG. 13, a lower pad-connecting metal layer 510 is formed on the carrier 100 including the solder bumps 300. When the connecting metal layer 400 is present on the carrier 100, the lower pad-connecting metal layer 510 may be formed on the connecting metal layer 400. At this point, the lower pad-connecting metal layer 510 may be formed on the carrier 100 including the solder bumps 300 by performing an electrolytic plating process using the metal foil 190 layered on the carrier 100 as a leading wire. In a subsequent process, the lower pad-connecting metal layer 510 constitutes the lowermost circuit layer of the resulting printed circuit board, and is patterned to have the lower connecting pads 515 being connected to the solder bumps 300. The lower pad-connecting metal layer 510 may be made of conductive metal, for example, copper, nickel, gold and silver. In this embodiment, the lower pad-connecting metal layer 510 is made of copper.

Subsequently, a build-up layer, which is composed of an insulating layer 600 and a circuit layer 503 electrically connected to the solder bumps 300, is formed on the lower pad-connecting metal layer 510. A process of forming the build-up layer may employ a subtractive technique, an additive technique, a semi-additive technique or a modified semi-additive technique. In this embodiment, the process of forming the build-up layer will be described as being conducted using the semi-additive technique.

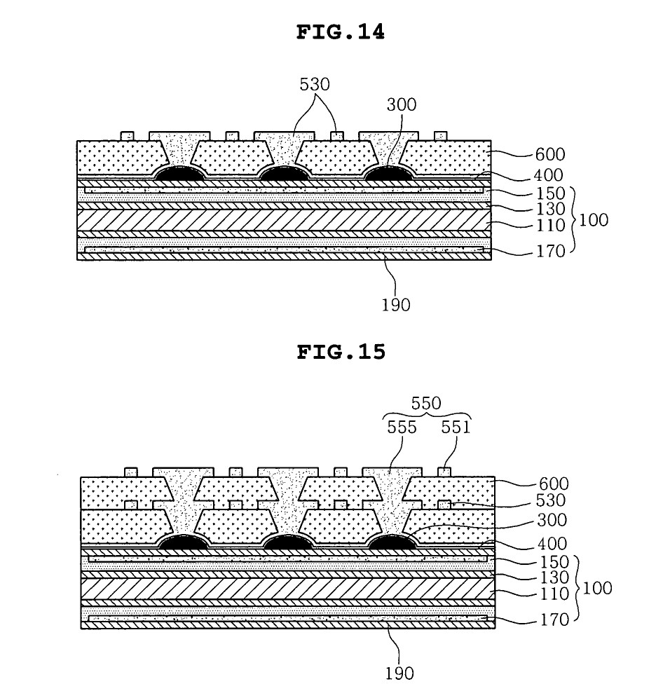

As shown in FIG. 14, an insulating layer 600 is formed on the lower pad-connecting metal layer 510, via-holes are formed at portions of the insulating layer 600 corresponding to the solder bumps 300 using laser drilling, for example, CO2 laser drilling. Then, electroless plating, application of a plating resist layer, patterning and electrolytic plating are sequentially performed, with the result that the build-up layer composed of the circuit layer 530 and the insulating layer 600 is created.

FIG. 15 is a cross-sectional view showing formation of an additional build-up layer on the circuit layer 530. The additional build-up layer may be formed in the same way as that described with reference to FIG. 14. By the formation of the additional build-up layer, an uppermost circuit layer 550 including upper connecting pads 555 and a circuit pattern 551 is created. Although only one additional build-up layer is formed in this embodiment, it will be apparent to those skilled in the art that further additional build-up layers may be formed if necessary. In other words, it should be noted that the scope of the present invention is not limited in terms of the number of build-up layers.

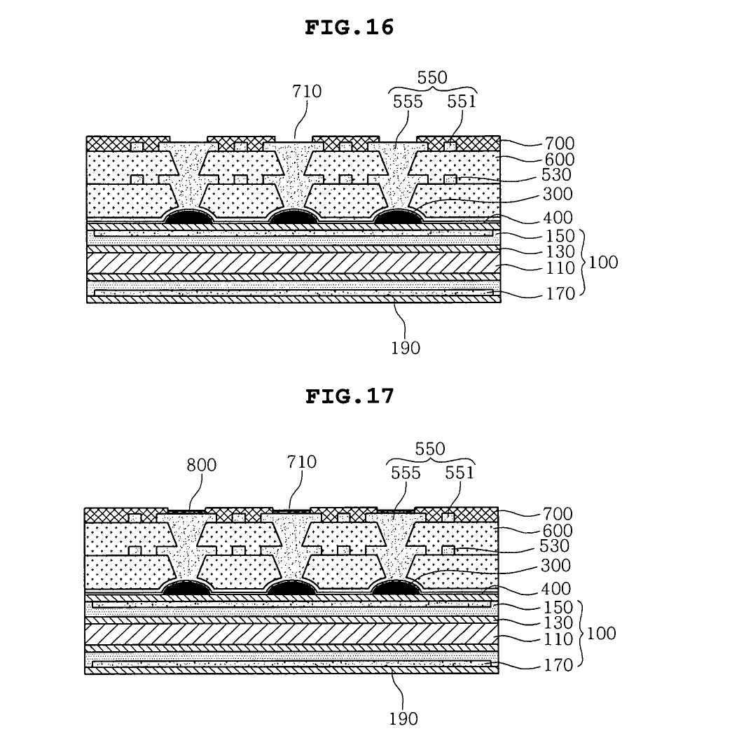

Thereafter, as shown in FIG. 16, a solder resist layer 700 having openings 710 through which the upper connecting pads 555 are exposed is formed on the uppermost circuit layer 550.

As shown in FIG. 17, surfaces of the upper connecting pads 555 may be optionally subjected to OSP (Organic Solderability Preservative) treatment or formation of an ENIG (Elctroless Nickel Immersion Gold) 800.

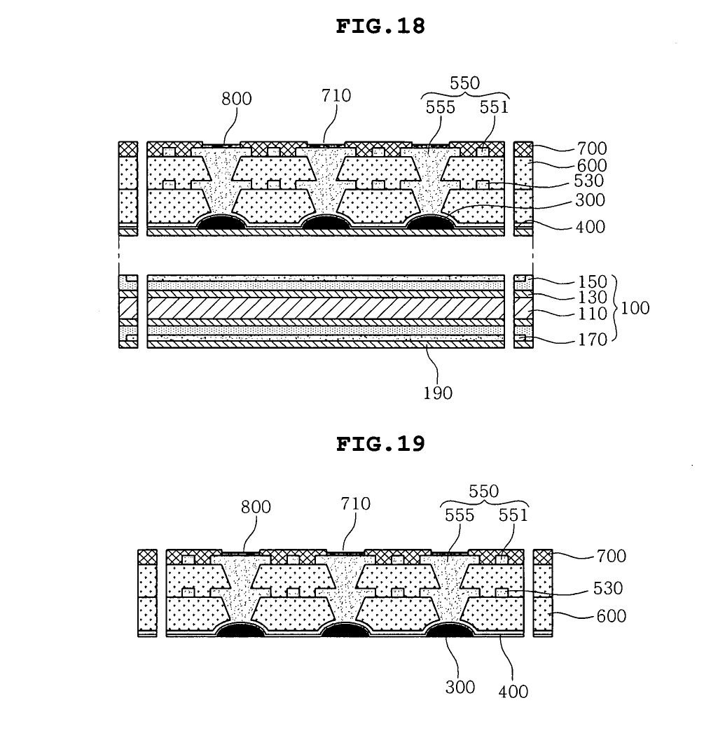

Next, as shown in FIG. 18, the carrier 100 is removed. At this point, lateral side portions of the carrier 100 and lateral side portions of the printed circuit board layered on the carrier 100 are cut away using a routing process, with the result that the carrier 100 can be removed from the metal foil 190 and the printed circuit board. In this regard, the routing process refers to a process of mechanically cutting and tring workpieces using a routing bit. By cutting and removing the lateral side portions of the printed circuit board and the carrier 100, the portions of the insulating layer 600 which hold the metal foil 190 layered on the carrier 100 are removed, thus allowing the metal foil 190 and the printed circuit board to be separated from the carrier 100.

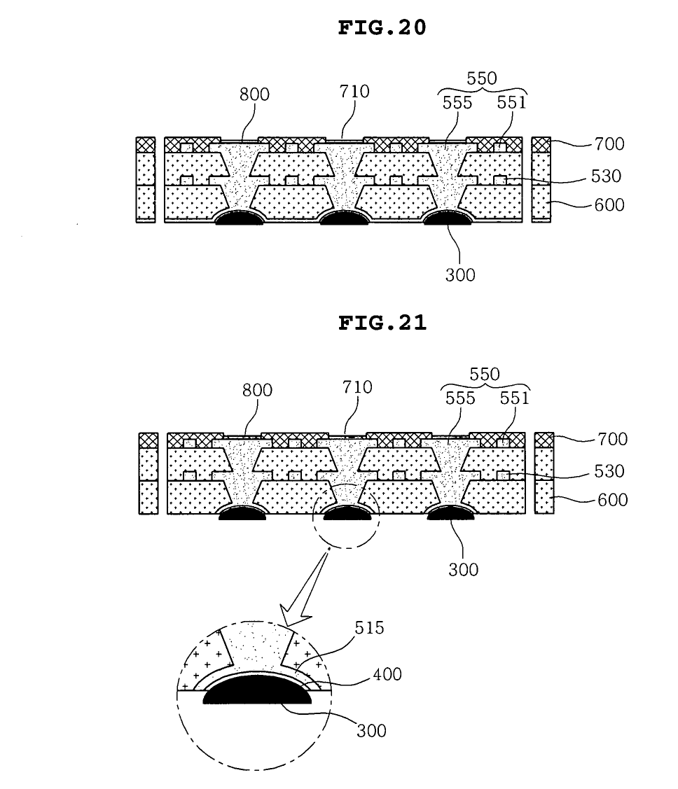

As shown in FIG. 19, the metal foil 190 is removed. If the connecting metal layer 400 is present, exposed portions of the connecting metal layer 400 are removed, as shown in FIG. 20. Then, as shown in FIG. 21, the exposed lower pad-connecting metal layer 510 is removed. As a result of the above process, the lower connecting pads 515 which are recessed in the insulating layer 600 to have a concave round shape are created.

In this embodiment, the metal foil 190, the exposed portions of the connecting metal layer 400 and the exposed portions of the lower pad-connecting metal layer 510 may be sequentially removed using respective etching solutions or may be removed all together using common etching solution.

In this case, when the connecting metal layer 400 is made of material different from that of the metal foil 190 and the lower pad-connecting metal layer 510, the different components may be sequentially removed using preferential etching solutions. When the metal foil 190 and the lower pad-connecting metal layer 510 are made of copper and the connecting metal layer 400 is made of nickel as in this embodiment, an etching process may be performed using nickel-preferential etching solution that selectively etches only nickel constituent. The nickel-preferential etching solution refers to solution that etches only nickel or nickel alloy constituent but does not etches copper. The nickel-preferential etching solution may be prepared by sulfuric acid solution of 550 ml/l-650 ml/l, mixed solution of sulfuric acid and nitric acid or mixed solution of sulfuric acid solution and m-nitrobenzene sulfonic acid.

By the above-described process, the printed circuit board having round solder bumps may be manufactured. In the above embodiment, although a process of providing a printed circuit board to only one side of the carrier 100 has been described for the convenience of explanation, two printed circuit boards may also be provided on both sides of the carrier 100 simultaneously.

In the process of manufacturing a printed circuit board having round solder bumps according to this embodiment, the rigid carrier 100 is printed with solder paste 310 through a screen printing process to thus form the solder bumps 300. Accordingly, base surfaces of the solder bumps are flattened and solder bumps having fine pitches can be provided. In addition, in the printing of the solder paste 310, a volume and a height thereof can be easily controlled, thus improving production yield.

Furthermore, since the exposed surfaces of the solder bumps 300 are configured to be flat, there is no need for conducting a bump coining process, thus reducing manufacturing costs.

The present invention also has an advantage in that it is not necessary to form a protective layer such as solder resist layer on the base surface of the solder bump 300.

Since the solder bumps 300 which has been subjected to a reflow process is first formed, a package board having solder balls formed thereon can be produced by conducting a reflow process only once after completion of a layering process of a printed circuit board, in which the reflow process may incur warp of the printed circuit board. As a result, a printed circuit board which has high packaging reliability and reduced warp can be obtained.

In addition, since the carrier 100 having no scale change is printed thereon with solder bumps 300, the solder bumps 300 can be formed to be positioned most close to the CAD designed value, and a matching accuracy in the connection with electronic components is improved.

As describe above, since the printed circuit board according the embodiment of the present invention has solder bumps which have the same height and are flush with an insulating material, coplanarity of solder bumps is achieved, thus ensuring reliable connection with electronic components mounted thereon.

Furthermore, since the round solder bumps have pad-connecting surfaces of round shape and thus a contact area with connecting pads is increased, a boding force between the solder bumps and the connecting pads is increased. Also, since the connecting pads are embedded in an insulating layer, it is possible to prevent the connecting pads from being separated from a printed circuit board in a test such as a ball shear test, thus drastically improving reliability of the solder bumps.

In the method of manufacturing a printed circuit board having round solder bumps according to the embodiment, since a rigid carrier is printed with solder paste using a screen printing technique to thus form solder bumps, base surfaces of solder bumps which come into contact with the carrier are flattened and solder bumps are formed at fine pitches. Furthermore, a volume and a height of solder bumps can be easily controlled in the printing of solder paste, and thus production yield is increased.

Additionally, since exposed surfaces of the solder bumps are formed to be flat, there is no need for conducting a bump coining process, thus reducing manufacturing costs.

Furthermore, since solder bumps which has been subjected to a reflow process is first formed, a package board having solder balls formed thereon can be produced by conducting a reflow process only once after completion of a layering process of a printed circuit board, in which the reflow process may incur warp of the printed circuit board. As a result, a printed circuit board which has high packaging reliability and reduced warp can be obtained.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

1. A printed circuit board comprising:
a plurality of circuit layers disposed one on other;
one or more insulating layer disposed between the plurality of circuit layers;
a lower connecting pad formed in a lowermost circuit layer of the plurality of circuit layers; and
a solder bump electrically connected to the lower connecting pad, in which a side of the solder bump, in contact with the lower connecting pad, has a round shape and the other side of the solder bump has a flat shape.

2. The printed circuit board according to claim 1, wherein the lower connecting pad has a concave round surface recessed in the insulating layer.

3. The printed circuit board according to claim 1, further comprising a connecting metal layer disposed between the lower connecting pad and the solder bump.

4. The printed circuit board according to claim 1, further comprising:
an upper connecting pad formed in a uppermost circuit layer of the plurality of circuit layers; and
a solder resist layer disposed on the uppermost circuit layer and having an opening through which the upper connecting pad is exposed.

5. The printed circuit board according to claim 3, wherein the connecting metal layer includes a nickel plating layer.

6. A method of manufacturing a printed circuit board, comprising:
forming a solder bump on a metal foil layered on a carrier, in which a pad-connecting surface of the solder bump, facing away from the carrier, has a round shape;
forming a lower pad-connecting metal layer on the metal foil including the solder bump;
forming a build-up layer on the lower pad-connecting metal layer, in which the build-up layer includes a circuit layer electrically connected to the solder bump and an insulating layer;
removing the carrier; and
removing the metal foil and an exposed portion of the lower pad-connecting metal layer.

7. The method according to claim 6, wherein forming the solder bump comprises:
disposing a printing mask on the metal foil layered on the carrier, in which the printing mask has an opening for formation of the solder bump, and printing the metal foil with solder paste; and
conducting a reflow process and removing the printing mask thus forming the solder bump.

8. The method according to claim 6, wherein the circuit layer formed in a uppermost circuit layer of the build-up layer includes an upper connecting pad, the method further comprising, after forming the build-up layer, forming a solder resist layer on the circuit layer formed in the uppermost portion of the build-up layer, in which the solder resist layer has an opening through which the upper connecting pad is exposed.

9. The method according to claim 6, further comprising, after forming the solder bump, forming a connecting metal layer on the metal foil including the solder bump, wherein removing the metal foil and the exposed portion of the lower pad-connecting metal layer comprises removing the exposed portion of the connecting metal layer.

10. The method according to claim 6, wherein the carrier comprises a copper clad laminate including an insulating layer and a thin copper layer layered on at least one side of the insulating layer and a release layer disposed on the copper clad laminate.

11. The method according to claim 7, wherein the printing mask includes a cover film having an opening for formation of the solder bump, in which the opening is formed in the cover film through an exposure/development process or a laser drilling process.

12. The method according to claim 7, wherein the printing mask includes a metal mask having an opening for formation of the solder bump.

13. The method according to claim 8, further comprising, after forming the solder resist layer, subjecting a surface of the solder resist layer to OSP (Organic Solderability Preservative) treatment or to formation of ENIG (Electroless Nickel Immersion Gold) layer.

14. The method according to claim 9, wherein the connecting metal layer includes a nickel plating layer.
